(19) United States
(12) Patent Application Publication
(10) Pub. No.: US 2013/0020676 A1
(43) Pub. Date: Jan. 24, 2013

(54) SOLENOID INDUCTOR FOR FREQUENCY SYNTHESIZER IN DIGITAL CMOS PROCESS

(71) Applicant: Chul Nam, Gyeonggi-do (KR)

(72) Inventor: Chul Nam, Gyeonggi-do (KR)

(21) Appl. No.: 13/520,877

(22) PCT Filed: Jan. 6, 2011
(86) PCT No.: PCT/KR2011/000090

§ 371 Date: Jul. 6, 2012

(30) Foreign Application Priority Data
Jan. 6, 2010 (KR) 10-2010-0000814

(51) Int. Cl. H01L 29/02

(52) U.S. Cl. 257/531; 257/E29.002

(57) ABSTRACT

The present invention relates to a solenoid inductor for a frequency synthesizer in a digital CMOS process. The solenoid inductor includes: a plurality of wiring metals configured in a solenoid structure with a given width wherein the wiring metals are stacked at two side regions in a vertical direction; and wiring metal connection means connecting the stacked side regions of the individual wiring metals in a vertical direction, wherein a given number of lower layer wiring metals among the wiring metals are connected through corresponding wiring metal connection means so as to completely overlap. Hence, by using a solenoid inductor to implement a frequency synthesizer operating at high frequency bands of 4 to 5 GHz or higher in a digital CMOS process, a frequency synthesizer operating at several GHz frequencies, which has been realized only in an RF CMOS process, can be implemented.

### BACKGROUND OF THE INVENTION

1. Field of the Invention

The present invention relates to a solenoid inductor for a frequency synthesizer in a digital CMOS process and, more particularly, to a solenoid inductor that can be used to implement a frequency synthesizer for high frequency bands of 4 to 5 GHz or higher in a digital CMOS process instead of a planar spiral inductor used in an existing RF process.

2. Description of the Related Art

Related art techniques for designing 4 to 5 GHz frequency synthesizers have always employed a CMOS RF process. This is because fabrication of an inductor, a passive element of a voltage controlled oscillator being a key component of a frequency synthesizer, requires thick top metal with a thickness of several micrometers or more. Among RF components, the inductor is regarded as a unit circuit component that occupies the largest area and heavily influences circuit performance. As it is more difficult to miniaturize an inductor than other unit circuit components, the inductor is considered an obstacle to enhancing integration levels of semiconductor devices exhibiting an analog behavior. In other words, as the integration level of semiconductor devices is heightened, unit circuit components such as transistors, resistors and capacitors are naturally downsized. Hence, it is not very difficult to miniaturize such unit circuit components. In contrast, it is difficult to miniaturize inductors by simply reducing sizes such as line widths or lengths. For example, to obtain a higher inductance with a given area, increasing the number of turns in the inductor may be considered first. However, as designing an inductor having a high inductance requires securing of suitable wire width and inter-wire gap in consideration of patterns of other layers, it is very difficult to realize high-quality inductors.

Inductor performance is mainly indicated by inductance (L) and quality factor (Q factor). As definitions of inductance and Q factor are widely known, they are not described further. It is known that the inductance of a semiconductor inductor is heavily influenced by the length and number of turns of wire. It is also known that the Q factor of a semiconductor inductor is greatly influenced by resistance of the wire at low frequencies, by signal loss of the substrate, and by symmetry of the inductor. Hence, to obtain a high inductance, it is necessary to realize an inductor that has a long wire with many turns in a wide area. To obtain a high Q factor, in realization of an inductor, it is necessary to use a low-resistance wire and a low-loss substrate and to maintain symmetry. For a high inductance, it is also important to design an inductor so that electric current does not flow in different or opposite directions.

FIGS. 1 to 3 illustrate semiconductor inductors in different shapes according to related art techniques.

FIG. 1 depicts a related art semiconductor inductor 10, which is a single-turn rectangular multi-layer inductor. In the inductor 10, single-turn unit inductors 11a, 11b and 11c in multiple layers are connected through vias 13a and 13b, and the final end is connected to the pass line 15 through a via 13c extending from the bottom layer to the top layer. As single-turn rectangular unit inductors are stacked in multiple layers, the inductor 10 may increase inductance. However, each unit inductor has just a single turn. As the inductor 10 is not symmetrical, it may experience severe inductance loss due to mutual inductance and cannot be used to construct a differential type inductor.

FIG. 2 depicts another related art semiconductor inductor 20, which is a multi-turn spiral inductor formed on a plane. The inductor 20 is connected through a via 23a with a pass line 25a formed on a different layer. The pass line 25a is connected through a via 23b to another pass line 25b formed on the same layer. As the inductor 20 is a multi-turn structure, it can achieve high inductance on the same plane. However, in upper and lower layers, electric currents flow in different or opposite directions, the inductor 20 necessarily experiences inductance loss. As the inductor 20 is not symmetrical, it may fail to obtain a high Q factor.

FIG. 3 depicts another related art semiconductor inductor 30. The inductor 30 is symmetrical on a plane, may have multiple turns, and includes multiple intersection portions 37a, 37b and 37c. Although the inductor 30 is symmetrical, it may fail to obtain sufficient inductance owing to multiple intersection portions. Specifically, inductance loss occurs at the intersection portions. Although the inductor 30 has a single layer structure on the whole, the intersection portions require multi-layer structures in part, resulting in a complicated fabrication process.

In a digital CMOS process, as thick top metal with a thickness of several micrometers is not used, an inductor used in an RF process is not suitable. Hence, it is necessary to develop an inductor that has high inductance and high Q factor with a smaller area.

### SUMMARY OF THE INVENTION

The present invention has been made in view of the above problems and the present invention provides a solenoid inductor that includes multiple wiring metals that are connected through vias to form a multi-layer structure, that has a high Q factor greater than 10 (Q>10), and that can be used to implement a frequency synthesizer in a digital CMOS process.

In accordance with an aspect of the present invention, there is provided a solenoid inductor for a frequency synthesizer in a digital CMOS process, including: a plurality of wiring metals configured in a solenoid structure with a given width wherein the wiring metals are stacked at two side regions in a direction perpendicular to a substrate; and wiring metal connection means connecting the stacked side regions of the individual wiring metals in a vertical direction, wherein a given number of lower layer wiring metals among the wiring metals are connected through corresponding wiring metal connection means so as to completely overlap, the wiring metals include first to third wiring metals and a top wiring metal, and a polysilicon pattern is formed under the first wiring metal to prevent leakage of magnetic flux to the substrate.

In accordance with another aspect of the present invention, there is provided a solenoid inductor for a frequency synthesizer in a digital CMOS process, including: a plurality of wiring metals configured in a solenoid structure with a given width, wherein the wiring metals are stacked at two side regions in a direction perpendicular to a substrate; and wiring metal connection means connecting the stacked side regions of the individual wiring metals in a vertical direction, wherein the wiring metals include fourth and subsequent wiring metals and a top wiring metal that are configured in a solenoid structure with a coil wound in a direction parallel to the substrate, magnetic flux of the solenoid inductor is directed in a direction horizontal to the substrate, and first to third wiring metals stacked to form the frequency synthesizer are placed under the fourth wiring metal of the solenoid inductor.

In a feature of the present invention, by using a solenoid inductor to implement a frequency synthesizer operating at high frequency bands of 4 to 5 GHz or higher in a digital CMOS process, a frequency synthesizer operating at several GHz frequencies, which has been realized only in an RF CMOS process, can be implemented.

Unlike an existing planar spiral inductor, the solenoid inductor of the present invention does not require thick metal, reducing inductor process cost.

Compared with the area of a spiral inductor, the area of a solenoid inductor can be reduced by up to 80 percent by vertically configuring the solenoid inductor, lowering chip fabrication cost.

Whereas a circuit cannot be placed under a spiral inductor owing to magnetic flux, a circuit can be placed under a solenoid inductor in a direction horizontal to magnetic flux. Hence, the solenoid inductor may reduce the area for realizing a frequency synthesizer and lower chip fabrication cost.

### BRIEF DESCRIPTION OF THE DRAWINGS

FIGS. 1 to 3 illustrate semiconductor inductors in different shapes according to related art techniques.

FIG. 4 is a sectional view of a solenoid inductor according to an embodiment of the present invention.

FIG. 5 is a perspective view of the solenoid inductor in FIG. 4.

FIGS. 6 and 7 illustrate structures to reduce resistance of the solenoid inductor.

FIG. 8 is a circuit diagram of a frequency synthesizer for high frequencies according to an embodiment of the present invention.

FIG. 9 shows an illustration in which a circuit is placed under the solenoid inductor.

FIG. 10 shows an illustration in which a polysilicon pattern is inserted under the solenoid inductor to reduce loss in the substrate.

FIG. 11 is a rear view of the polysilicon pattern in FIG. 10.

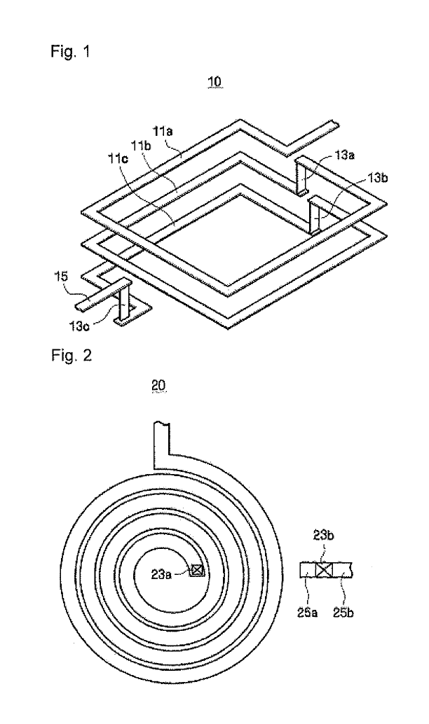

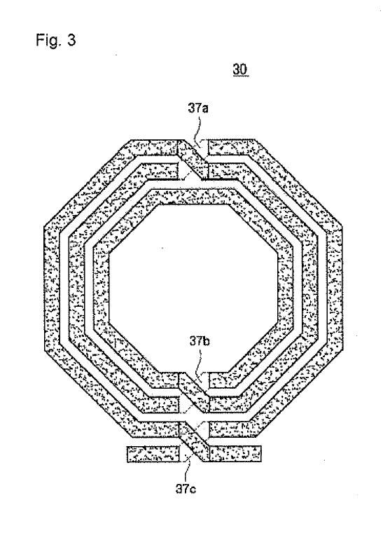

### DETAILED DESCRIPTION OF EXEMPLARY EMBODIMENTS

Hereinafter, exemplary embodiments of the present invention are described in detail with reference to the accompanying drawings. Particular terms may be defined to describe the invention in the best manner. Accordingly, the meaning of specific terms or words used in the specification and the claims should not be limited to the literal or commonly employed sense, but should be construed in accordance with the spirit of the invention. The description of the various embodiments is to be construed as exemplary only and does not describe every possible instance of the invention. Therefore, it should be understood that various changes may be made and equivalents may be substituted for elements of the invention.

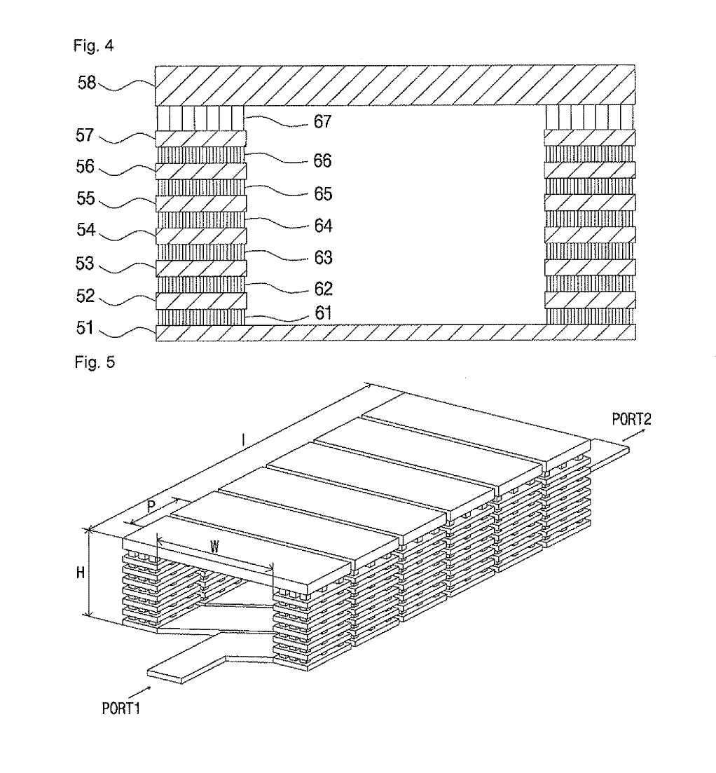

FIG. 4 is a sectional view of a solenoid inductor according to an embodiment of the present invention.

The solenoid inductor shown in FIG. 4 is fabricated to realize a frequency synthesizer operating at high frequency bands of 4 to 5 GHz or higher in a digital CMOS process. The solenoid inductor is fabricated using wiring metals. As shown in FIG. 4, first to seventh wiring metals 51 to 57 and top wiring metal 58 are stacked to form a multi-layer structure. Among the wiring metals 51 to 58, the first wiring metal 51 is thinnest and the top wiring metal 58 is thickest; and the remaining wiring metals 52 to 57 have the same thickness. The wiring metals 51 to 58 are separated from one another by insulation layers (not shown), and are connected to one another through vias 61 to 67.

FIG. 5 is a perspective view of the solenoid inductor shown in FIG. 4.

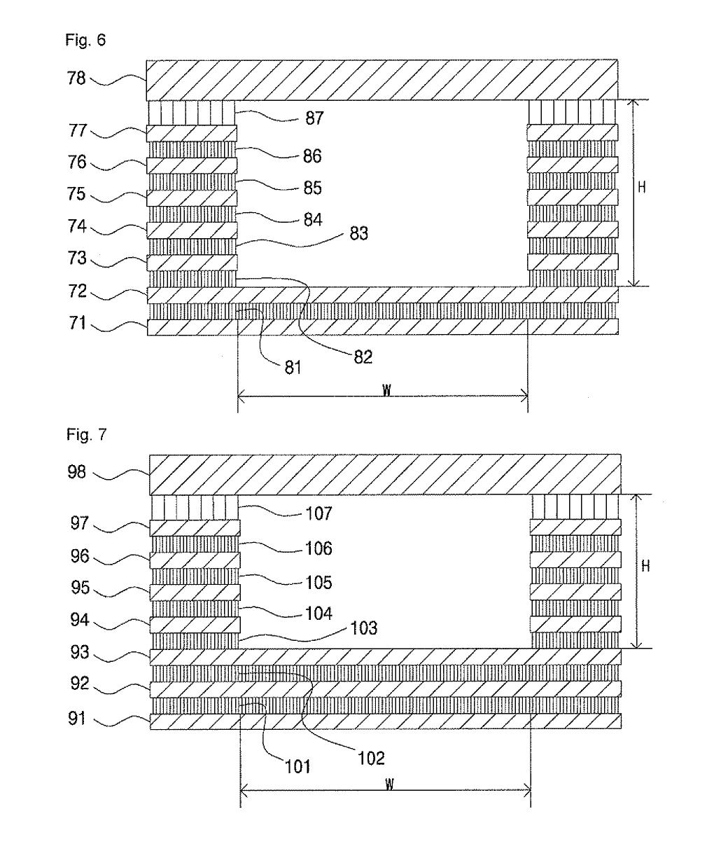

Referring to FIG. 5, the inductance of the solenoid inductor is determined by magnetic flux formed within the structure when electric current flows in a direction from PORT1 to PORT2. Assuming the length (l) is greater than the width (w), the inductance is given by: L=4π×10⁻⁷*n*w*h/p, where n is the number of turns. In a semiconductor process, as the height of the solenoid inductor is not adjustable and is set to several micrometers, the inductance may be adjusted by altering the number of turns (n) and width (w). Characteristics of an inductor may be indicated by the quality factor Q and self-resonance frequency (SRF). The quality factor is given by Q=ωL/R. SRF is determined by internal parasitic capacitance of an inductor, and the inductor behaves as an inductor in frequencies below SRF. In the case of a solenoid inductor, as internal parasitic capacitance is small, SRF is in a frequency range of dozens of GHz. Hence, the solenoid inductor can be used without problems in a frequency band of several GHz. However, the quality factor depends on the resistance (R) of the solenoid inductor. In a frequency band of several GHz, as current flows along the surface of the inductor by skin effect, the resistance of the solenoid inductor increases. At a frequency of 5 GHz, as the skin depth caused by skin effect is several micrometers, all current flows along a metal with a thickness of up to several micrometers in a CMOS process. When a metal is thin, the resistance thereof is large, lowering the quality factor. To handle this situation, as shown in FIGS. 6 and 7, two or more metals are stacked so as to reduce the resistance.

FIGS. 6 and 7 illustrate structures to reduce resistance of the solenoid inductor.

In FIG. 6, the solenoid inductor includes first to seventh wiring metals 71 to 77 and top wiring metal 78. The wiring metals 71 to 78 are separated from one another by insulation layers (not shown), and are connected to one another through vias 81 to 87. Here, the first and second wiring metals 71 and 72 are connected through vias 81 so as to overlap. In FIG. 7, the solenoid inductor includes first to seventh wiring metals 91 to 97 and top wiring metal 98. The wiring metals 91 to 98 are separated from one another by insulation layers (not shown), and are connected to one another through vias 101 to 107. Here, the first to third wiring metals 91 and 93 are connected through vias 101 and 102 so as to overlap. The solenoid inductor configured as shown in FIG. 6 or 7 can have a low resistance, enhancing the quality factor Q. Here, a decrease in inductance caused by the reduced height (h) may be compensated for by increasing the width (w).

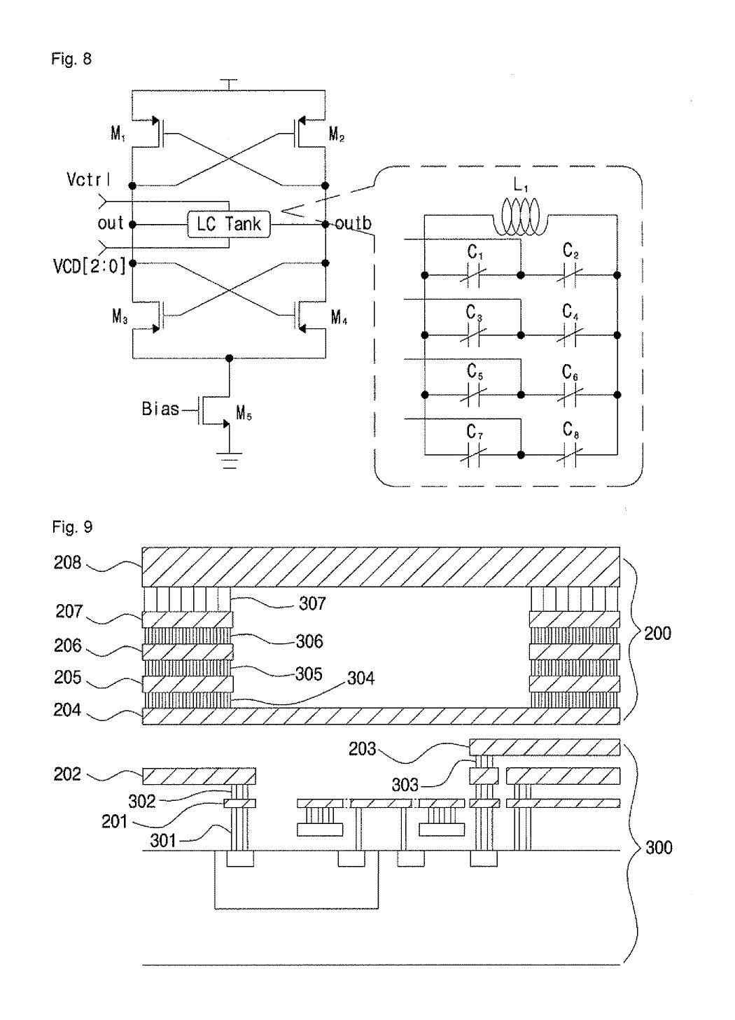

FIG. 8 is a circuit diagram of a frequency synthesizer for high frequencies according to an embodiment of the present invention.

As shown in FIG. 8, the frequency synthesizer includes an LC-tank circuit and an oscillator circuit. In the LC-tank circuit, the solenoid inductor of the present invention is used, and MOS capacitors or MOS varactors provided by a digital process are used. A metal-insulator-metal (MiM) structure may be added. In particular, unlike an existing spiral inductor, as magnetic flux of the solenoid inductor is directed in a horizontal direction to the substrate, the amount of eddy current induced by the magnetic flux is small. Hence, as shown in FIG. 9, it is possible to place a circuit under the solenoid inductor.

FIG. 9 shows an illustration in which a circuit is placed under the solenoid inductor.

In FIG. 9, the frequency synthesizer circuit 300 is placed under the solenoid inductor 200. Fourth to seventh wiring metals 204 to 207 and a top wiring metal 208 are configured in a solenoid structure by stacking both ends of the wiring metals together in a direction perpendicular to the substrate and winding the coil in a direction parallel to the substrate. The wiring metals are separated from one another by insulation layers (not shown), and are connected to one another through vias 304 to 307. As described before, in the solenoid inductor 200, magnetic flux is directed in a direction horizontal to the substrate. Hence, under the solenoid inductor 200, first to third wiring metals 201 to 203 connected through vias 301 to 303 may be placed to form the frequency synthesizer circuit.

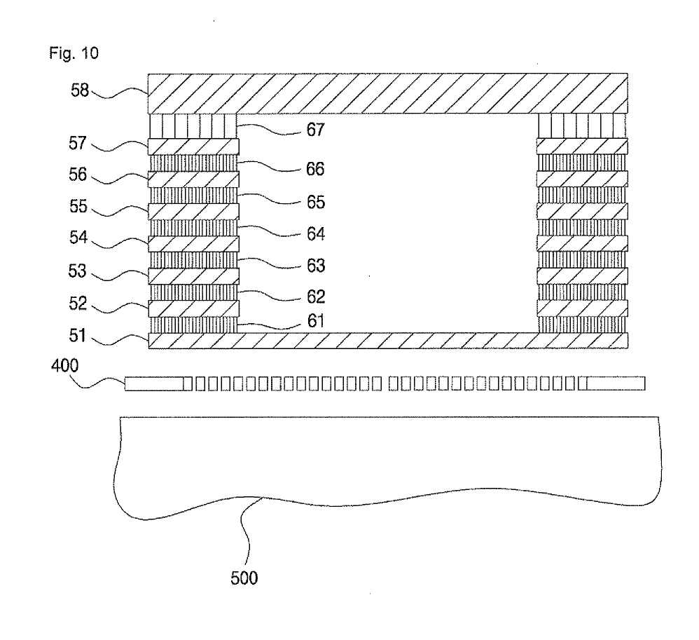

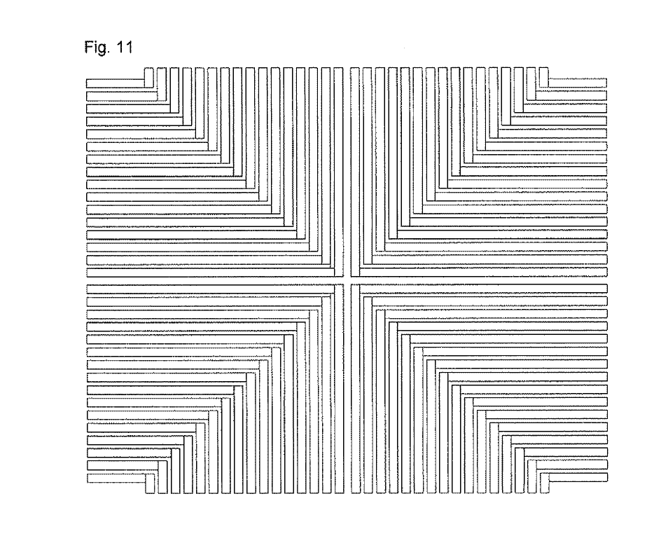

FIG. 10 shows an illustration in which a polysilicon pattern is inserted under the solenoid inductor to reduce loss in the substrate. FIG. 11 is a rear view of the polysilicon pattern in FIG. 10.

In FIG. 10, to form a solenoid inductor, first to seventh wiring metals 51 to 57 and top wiring metal 58 are stacked as a multi-layer structure. Among the wiring metals 51 to 58, the first wiring metal 51 is thinnest and the top wiring metal 58 is thickest; and the remaining wiring metals 52 to 57 have the same thickness. The wiring metals 51 to 58 are separated from one another by insulation layers (not shown), and are connected to one another through vias 61 to 67. A polysilicon pattern 400 of an ‘L’ shape is inserted under the solenoid inductor to prevent magnetic flux of the solenoid inductor from leaking into the substrate 500. Hence, inductance loss of the substrate can be reduced to thereby increase the quality factor.

In the above description, the solenoid inductor is depicted as having eight layers of wiring metals (the eighth layer as the top). However, the solenoid inductor may have eight or more layers of wiring metals according to process requirements.

Although the present invention has been described using limited embodiments and drawings, it should be understood that many variations and modifications of the basic concept described herein will still fall within the scope of the present invention as defined in the appended claims.

What is claimed is:

1. A solenoid inductor for a frequency synthesizer in a digital CMOS process, comprising:
a plurality of wiring metals configured in a solenoid structure with a given width wherein the wiring metals are stacked at two side regions in a direction perpendicular to a substrate; and
wiring metal connection means connecting the stacked side regions of the individual wiring metals in a vertical direction,
wherein a given number of lower layer wiring metals among the wiring metals are connected through corresponding wiring metal connection means so as to completely overlap.

2. The solenoid inductor of claim 1, wherein the wiring metals include first and subsequent wiring metals and a top wiring metal stacked at two side regions in a perpendicular direction.

3. The solenoid inductor of claim 2, wherein a polysilicon pattern is formed under the first wiring metal to prevent leakage of magnetic flux to the substrate.

4. The solenoid inductor of claim 2, wherein the first wiring metal and the second wiring metal stacked on the first wiring metal are connected through wiring metal connection means between the first and second wiring metals so as to completely overlap each other.

5. The solenoid inductor of claim 2, wherein the first wiring metal, the second wiring metal stacked on the first wiring metal and the third wiring metal stacked on the second wiring metal are connected through wiring metal connection means between the first and second wiring metals and between the second and third wiring metals so as to completely overlap each other.

6. A solenoid inductor for a frequency synthesizer in a digital CMOS process, comprising:
a plurality of wiring metals configured in a solenoid structure with a given width, wherein the wiring metals are stacked at two side regions in a direction perpendicular to a substrate; and
wiring metal connection means connecting the stacked side regions of the individual wiring metals in a vertical direction,
wherein the wiring metals include fourth and subsequent wiring metals and a top wiring metal that are configured in a solenoid structure with a coil wound in a direction parallel to the substrate, magnetic flux of the solenoid inductor is directed in a direction horizontal to the substrate, and first to third wiring metals stacked to form the frequency synthesizer are placed under the fourth wiring metal of the solenoid inductor.
